(19) United States
(12) Patent Application Publication
(10) Pub. No.: US 2006/0091794 A1
(43) Pub. Date: May 4, 2006

(54) Passive matrix OLED display having increased size

(75) Inventors: John A. Agostinelli, Rochester, NY (US); Marek W. Kowarz, Henrietta, NY (US); Liang-Sheng Liao, Rochester, NY (US)

Correspondence Address: Paul A. Leipold;Patent Legal Staff, Eastman Kodak Company, 343 State Street, Rochester, NY, 14650-2201, US

(73) Assignee: Eastman Kodak Company

(21) Appl. No.: 10/981,205

(22) Filed: Nov. 4, 2004

(51) Int. Cl. H05B 33/00; H05B 33/02; H05B 33/10

(52) U.S. Cl. 313/506; 313/500; 313/503; 445/24

(57) ABSTRACT

A passive matrix OLED display free of line dropout defects in the image region and providing full-frame brightness of at least 50 nits is disclosed. In one embodiment of the invention, the display may have a diagonal surface dimension in excess of 10 inches and may have more than 150 row lines. In a specific embodiment, a passive matrix OLED display is described comprising an array of individually addressable OLED pixels arranged in column and row lines in an imaging area of the display, wherein at least one pixel comprises at least one current-limiting component connected in series with an electroluminescent diode, and wherein the electroluminescent diode comprises a plurality of electroluminescent units connected in series between an anode and a cathode.

### FIELD OF THE INVENTION

This invention generally relates to OLED displays and more particularly relates to a passive matrix OLED display having significantly increased surface area and brightness over previous passive matrix OLED designs.

### BACKGROUND OF THE INVENTION

Organic Light Emitting Diode (OLED) technology holds significant promise as a display technology that is well-suited to a broad range of applications. Self-emitting OLED displays are advantaged over other display technologies, requiring no external light source and supporting optics and providing high luminance, good quality color, and relatively wide viewing angle. OLED display components are thin and lightweight, making them particularly adaptable for use with handheld components, such as cameras, cell phones, personal digital assistants (PDAs) and laptop computing devices.

The basic bottom-emitting OLED pixel 10 is constructed as shown in FIG. 1. An organic layer 12, typically fabricated as a stack of multiple thin organic layers, is sandwiched between a cathode 14 and a transparent anode 16, built onto a glass substrate 18. Organic layer 12 includes an electroluminescent (EL) layer that provides illumination when appropriate voltage is applied between anode 16 and cathode 14. Pixel 10 is formed in the overlap area between cathode 14 and anode 16. An OLED display is formed from an ordered spatial arrangement of individually addressable OLED pixels 10 arranged as an array, in successive rows and columns.

The organic EL medium layer 12 disposed between the anode and the cathode is commonly comprised of an organic hole-transporting layer (HTL) and an organic electron-transporting layer (ETL). Holes and electrons recombine and emit light in the ETL near the interface of HTL/ETL. Tang et al., “Organic electroluminescent diodes”, Applied Physics Letters, 51, 913 (1987), and commonly assigned U.S. Pat. No. 4,769,292, demonstrated highly efficient OLEDs using such a layer structure. Since then, numerous OLEDs with alternative layer structures have been disclosed. For example, there are three-layer OLEDs that contain an organic light-emitting layer (LEL) between the HTL and the ETL, such as that disclosed by Adachi et al., “Electroluminescence in Organic Films with Three-Layer Structure”, Japanese Journal of Applied Physics, 27, L269 (1988), and by Tang et al., “Electroluminescence of doped organic thin films”, Journal of Applied Physics, 65, 3610 (1989). The LEL commonly includes of a host material doped with a guest material wherein the layer structures are denoted as HTL/LEL/ETL. Further, there are other multilayer OLEDs that contain a hole-injecting layer (HIL), and/or an electron-injecting layer (EIL), and/or a hole-blocking layer, and/or an electron-blocking layer in the devices. These structures have further resulted in improved device performance.

There are two basic types of OLED arrays, passive matrix and active matrix. Active-matrix OLED displays integrate current control circuitry within the display itself, having separate control circuitry dedicated for each individual pixel element on the substrate. Active matrix displays have been shown capable of providing high-resolution color graphics at a high refresh rate with good brightness at low peak pixel drive current levels. Active matrix display circuitry is disclosed in U.S. Pat. Nos. 6,392,617 entitled “Active Matrix Light Emitting Diode Display” to Gleason and 6,433,485 entitled “Apparatus and Method of Testing an Organic Light Emitting Diode Array” to Tai et al, for example. In an active matrix OLED display, each pixel requires built-in switching transistors and other control circuitry, contributing to the cost and complexity of these devices, per pixel.

The basic arrangement of a passive matrix OLED array 20 is shown in the simplified schematic of FIG. 2. In array 20, each individually addressable pixel 10 has a light-emitting diode 11 connected between an anode line 26 (column) and a cathode line 24 (row). Each anode line 26 has a current source 22 that is switched ON to anode line 26 in order to illuminate pixel 10 in each column, according to image data. Cathode line 24 is commonly shared by each light-emitting diode 11 in a row. A selection switch 30 for each cathode line 24 switches to ground to enable illumination of pixels 10 in each successive row, one row at a time, using a scanned row selection sequence. A light-emitting diode 11 illuminates when its current source 22 is switched ON and its corresponding row selection switch 30 switches to ground. Otherwise, cathode lines 24 are typically switched to an intermediate voltage Vᵢ. Light-emitting diodes 11 whose cathode potential is at Vᵢ do not illuminate. Having its cathode line 24 at intermediate voltage Vᵢ turns pixels 10 off for any row that is not being selected, but maintains some potential on the row. This reduces the amount of power necessary to charge the parasitic capacitance of each row as it is addressed. Using this straightforward arrangement, passive matrix OLED array 20 can be constructed to have several thousand pixels 10, organized in a matrix of rows and columns. Control logic in a display apparatus (not shown) provides control of current source 22 for each column and of selection switch 30 for each row, making each OLED pixel 10 individually addressable, using control and timing techniques well known in the display component arts.

It must be emphasized that the above description and schematic of FIG. 2 provide a simplified explanation of the control mechanisms and composition of passive matrix OLED array 20. More detailed information on prior art passive matrix OLED arrays and array driver solutions can be found, for example, in U.S. Pat. No. 5,844,368 entitled “Driving System for Driving Luminous Elements” to Okuda et al. and in U.S. Pat. No. 6,594,606 entitled “Matrix Element Voltage Sensing for Precharge” to Everitt.

By comparison, passive-matrix OLED displays are of simpler construction than are active-matrix displays, having current control circuitry that is external to the display itself. Thus, passive-matrix OLED displays, with fewer support components per pixel integrated on the display component itself, allow simpler, lower cost fabrication techniques than their active-matrix counterpart. Active matrix displays, on the other hand, have in general been advantaged over passive matrix devices with respect to brightness and overall efficiency. One inherent advantage enjoyed by active matrix devices relates to how pixels are addressed and to the relative duration of luminescence for each individual pixel. Given the benefit of built-in support circuitry, the active matrix arrangement allows electroluminescence at each individual pixel over a prolonged period relative to that of passive matrix pixels. Moreover, the row-column addressing scheme required for energizing pixels one row at a time in a passive matrix display requires a very high momentary brightness level from each line. For example, for a brightness level of (n units) in a 100 line passive matrix display, each line must be (100×n units) in brightness, since each line is energized for 1/100^{th} of the time. Under standard office or home viewing conditions, a display must produce a full-frame time-averaged brightness of at least 50 nits. Among other factors, this requirement for high brightness imposes practical constraints on overall display size when using passive matrix designs. A further disadvantage of these devices relates to current-carrying requirements for driver support components, needed to handle the momentary high-current pulse for each individual row of passive matrix OLED devices.

While smaller passive-matrix OLED displays of a few inches in diagonal have been successfully built, it is a common belief among researchers in the display arts that there are significant constraints inherent to large passive-matrix OLED designs. Evidence of this can be seen, for example, in research publications such as in the article entitled “OLED Technology Rolls Toward Reality” in COTS Journal, March, 2003, pp. 25-27. This article states that efficiency limitations constrain the potential dimensions of passive-matrix OLED displays to no greater than 2-3 or 100 display lines. Power efficiency considerations are also cited as a constraint for providing a large-scale passive-matrix OLED display having sufficient brightness in a paper entitled “Patterning Approaches and System Power Efficiency Considerations for Organic LED Displays” by J. C. Sturm, et al. Still further, a press release from Toshiba Corporation (currently available at www.toshiba.co.jp/about/press/2001_{—}05/pr3001.htm) states that a large-scale, full-color OLED requires an active matrix design, as opposed to a passive matrix configuration. A recent article (currently available at www.extremetech.com) appears to summarize the general attitude of the research community, stating: “Active matrix OLEDs are targeted at high-resolution displays, whereas passive matrix OLEDs are geared towards ‘low-information’ displays.”

Although passive matrix components have simpler fabrication than is needed for active matrix components, this advantage is largely eroded by the relative significance of defects for passive matrix design. Fabrication defects present significant obstacles to the development of large area OLED displays of the passive matrix type. Defects may be due to dust or contamination during fabrication, asperities due to electrode surfaces, pinholes, and non-uniformities in organic layer thickness, for example.

Of particular concern for display operation is the defect caused by a shorted diode 11. Referring back to FIG. 2, it can be observed that a shorted diode 11 for a pixel 10 effectively connects current source 22 directly to ground when the corresponding row is selected. When other rows are selected, a shorted diode 11 effectively sets intermediate voltage Vᵢ onto anode line 26. Because of this, the complete column of pixels 10 is blacked out during display operation. Whereas some number of individual dead pixels 10 can be tolerated in a viewed image, defects affecting an entire line, in general are not acceptable. Thus, in practice, there is zero tolerance for shorted pixel defects over the entire area of passive matrix OLED array 20.

FIGS. 3a, 3b, 3c, and 3d show how various configurations of passive matrix OLED array 20 behave in response to a shorted diode condition. FIGS. 3a, 3b, and 3c show OLED array 20 where row selection switches 28 are either open or closed (to ground), without connection to intermediate voltage Vᵢ. Referring first to FIG. 3a, there is shown a small section of OLED array 20 having light-emitting diodes 11a, 11b, 11c, and 11d at individually addressable pixels 10a, 10b, 10c, and 10d, respectively, in an arrangement of rows 44a and 44b and columns 42a and 42b. In the example of FIG. 3a, diode 11d is shorted, as indicated by a short 46. During row scanning, row 44a is enabled, while adjacent row 44b is disabled, as shown at respective switches 28. Current source 22 for a column 42a is ON to illuminate pixel 10a (by providing current through light-emitting diode 11a) at the intersection of column 42a and row 44a. However, short 46 is at the position of pixel 10d for the next row 44b at a column 42b. Short 46 thus provides an unwanted current path to column 42b, through diode 11c. Depending on the amount of current flowing through short 46, diode 11c may illuminate, thereby being permanently ON for scanning all rows 44 in array 20. Even dim constant illumination of diode 11c would be undesirable. As FIG. 3b shows, when both current sources 22 are ON, pixel 10c would have the desired state. As FIG. 3c shows, when row 44b is selected, and diode 11c is ON, short 46 would be effectively bypassed.

Referring to FIG. 3d, there is, shown an OLED array 20 arrangement in which row selection switch 28 is at intermediate voltage Vᵢ until a row is selected. With short 46 in the position shown, when selection switch 28 for row 44b connects to idle voltage Vᵢ and when row 44a is selected (scanned), or any other row except row 44b is selected (scanned), column 42b is held at Vᵢ. Because of this, column 42b is effectively disabled. It is instructive to observe that current source 22 is designed to provide current to only a single light emitting diode 11 at a time; meanwhile, intermediate voltage Vᵢ is provided to a full row 44a, 44b. It would be unpractical to size current source 22 in each column 42a, 42b to compensate for the condition caused by short 46.

The likelihood of a fabrication defect increases dramatically as the display area increases. Assuming that the overall defect density for array 20 exhibits a Poisson distribution characteristic, then the probability that array 20 has zero defects is the yield Y and can be expressed in the equation (1):
Y=e^{-DA} (1)
where D is a the shorting defect density per area and, for a shorted diode 11, A is the full area of array 20.

The exponential scaling impact of defect, density D and area A in equation (1) is particularly significant. For example, for a reasonable defect density D of 0.01 per square cm and an area A of 0.5 square meter, the yield Y is as follows:
Y=2×10⁻²²
In other words, chances for a good display yield with a very large passive-matrix OLED display, using conventional techniques, are practically nil. Only a dramatic reduction of factors D and/or A in the exponent of equation (1) can allow a reasonable yield for OLED arrays.

U.S. Pat. No. 6,605,903 to Swallow discloses a passive matrix array having sections that can be selectively activated or deactivated to compensate for OLED pixel 10 defects. In the OLED array of U.S. Pat. No. 6,605,903, each column has two separate sections, either of which can be activated or deactivated in the event of a shorted diode. While this approach can mitigate defect problems, the array requires a considerable number of additional components, many of which would not be used. Moreover, defects occurring after manufacture, and testing would still have a negative effect on display performance.

Although not directed to an OLED array used for addressable image display, U.S. Patent Application Publication 2002/0190661 A1 discloses a serial connection of multiple, large area OLED modules directly to an AC power source for room lighting and signage applications. Each OLED cell or module is a single diode, having an emissive surface that is at least a few square centimeters in area. OLED cells are connected in series fashion, with the anode of one OLED cell connected to the cathode of the previous one, for example. Advantageously for the lighting and signage lettering uses described in U.S. Patent Application Publication 2002/0190661 A1, this solution permits OLED devices to be used with alternating current at line voltage (nominally at 120 VAC, 60 Hz), so that a separate DC power supply is not required. Series-connected OLED cells are arranged to illuminate during each half cycle of AC current. In a paper entitled “Fault-tolerant, scalable organic light-emitting device architecture” in Applied Physics Letters, Vol. 82, Number 16, 21 Apr. 2003, this type of series connection for large area OLED cells for illumination applications is also disclosed and further discussed with reference to the impact of faults on other OLED devices in the series. Not surprisingly, a shorted OLED cell diode in the series causes a corresponding increase in brightness among other OLED cells in the same series.

Copending, commonly assigned U.S. patent application Ser. No. 10/773,509 entitled “OLED Display Apparatus Having Improved Fault Tolerance” by Agostinelli et al., filed on Feb. 6, 2004, the disclosure of which is incorporated by reference herein, describes passive matrix OLED arrays having improved fault tolerance, where the array has a plurality of column electrodes and a plurality of rows of individually addressable OLED pixels, each row including a commonly shared electrode, wherein at least one OLED pixel in each row has a current limiting component and an organic electroluminescent diode and such at least one OLED pixel is connected between said commonly shared electrode and one of the plurality of column electrodes for conducting current therebetween, and the at least one organic electroluminescent diode is connected in series with the current limiting component. Such arrangement provides a low-cost addition to OLED array fabrication that reduces the likelihood of a dark OLED line defect in a display, thus permitting increased yields in OLED array manufacture by limiting one cause of line dropout due to shorting of a single pixel.

Another problem for large-scale display design using passive-matrix technology relates to luminous efficiency characteristics of OLEDs. It is widely recognized that conventional efficiencies, typically on the order of a few cd/A (candelas per ampere), are insufficient for realizing large passive matrix displays. Initial OLED designs, such as disclosed in commonly assigned U.S. Pat. No. 4,769,292 entitled “Electroluminescent Device with Modified Thin Film Luminescent Zone” to Tang et al., employed singlet state emission (“fluorescence”). Later research showed that singlet state emission is constrained to an upper limit of efficiency of about 25%. More recently developed OLED materials using triplet exciton emission (“phosphorescence”), as described in U.S. Pat. No. 6,303,238, entitled “OLEDs Doped with Phosphorescent Compounds” to Thompson, et al., show promise of much higher relative efficiencies. Unfortunately, however, the luminous efficiency of these devices drops as a function of drive current density, as is described in U.S. Pat. No. 6,645,645 entitled “Phosphorescent Organic Light Emitting Devices” to Adachi et al. and in International Application, Publication Number WO 00/70655 entitled “Very High Efficiency Organic Light Emitting Devices Based on Electrophosphorescence” by Baldo et al. Because passive matrix addressing requires much higher drive current densities than are typically needed for active matrix devices, the compromised efficiency of these devices with increased current levels does not at all suggest passive matrix technology as a promising solution for the problem of obtaining higher brightness levels.

Another development which might appear to offer some promise for achieving higher luminous efficiency for passive matrix OLED designs is the use of a stacked (or tandem or cascaded) arrangement of OLED diode junctions within each single pixel, such as described in U.S. Patent Publication No. 2003/0170491 A1 entitled “Providing an Organic Electroluminescent Device Having Stacked Electroluminescent Units” by Liao et al., the disclosure of which is incorporated herein by reference. So-called Stacked OLEDs (SOLEDs) may be capable of providing improved color quality and higher resolution. SOLEDs effectively have multiple emissive diodes connected in series, resulting in a multiplication of the inherent luminous efficiency of these devices. The layer structure of a stacked OLED comprises an anode, a cathode, a plurality of organic EL units and a plurality of organic connectors (or connecting units hereafter), wherein each of the connecting units is disposed between two organic EL units. The organic EL unit includes at least one light-emitting layer, and typically comprises, in sequence, a hole-transport layer, a light-emitting layer, and an electron-transport layer, denoted in brief as HTL/LEL/ETL. The emitting diode layers within the stack are called emitter units. Thus, for a given amount of drive current, an OLED stack with a number n of emitter units can theoretically provide n times the light output (at n times the voltage). However, prior art again shows that, for triplet emission components, luminous efficiency degrades as a function of current density. Referring to FIG. 4 (and as disclosed in FIG. 3(b) of Applied Physics Letters 84(2), 167(2004)), curve 32a shows efficiency for a single layer triplet emitter as a function of current density. Curves 32b and 32c in FIG. 4 show efficiency behavior for triplet material two- and three-layer stacked OLEDs respectively. Thus, even though stacked OLED devices offer some potential advantages for added brightness, this advantage can be mitigated by the loss of efficiency at increased current density levels, where large passive matrix OLED displays would find their operating points. As is seen in FIG. 4, the drop-off in current efficiency is exacerbated for SOLED devices as the number n increases.

To date, then, a number of problems have prevented the development and commercialization of large area OLED displays of the passive matrix type. Frustrated by low fabrication yields, performance constraints, relatively high power consumption, efficiency drop-off at high current densities, and brightness limitations of conventional passive-matrix design approaches, researchers interested in large-scale QLED displays have primarily focused on active-matrix, rather than passive-matrix OLED designs. In addition, expectations of higher efficiencies using triplet-emission materials have steered researchers away from consideration of singlet-emission materials for large-scale OLED displays. Thus, once again, as emphasized above, the conventional teaching of those skilled in the display arts directs attention toward active-matrix designs for large-scale OLED displays, away from passive-matrix solutions and away from solutions providing singlet emission.

While there have been a few solutions proposed for limiting or minimizing the impact of a faulted OLED on other nearby OLEDs, none of these solutions is particularly well suited for use with a passive matrix OLED array used in imaging display applications, where each OLED electroluminescent diode 11 serves as one individually addressable pixel 10 for forming an image. The active matrix designs disclosed in U.S. Pat. Nos. 6,392,617 and 6,433,485 add considerable complexity, as does the dual-column solution disclosed in U.S. Pat. No. 6,605,903. The solution proposed in U.S. Patent Application Publication 2002/0190661 A1 applies for discrete, modular OLED lighting devices that are used as banks of large-scale illuminators, rather than for OLED arrays where each individually addressable OLED electroluminescent diode 11 serves as one pixel 10 for forming an image.

Thus, it can be seen that, while it is widely held among those skilled in the display arts that passive-matrix OLEDs are uncapable of providing commercially viable large-scale displays having sufficient brightness, there would be significant advantages to providing a large-scale display of this type that meets market demands for high brightness and good resolution and color, and that enjoys the cost advantages and simpler design of passive-matrix fabrication.

### SUMMARY OF THE INVENTION

It is an object of the present invention to provide a large-scale OLED display having sufficient brightness using a passive-matrix OLED design. With this object in mind, the present invention in one embodiment provides a passive matrix OLED display comprising an array of individually addressable OLED pixels arranged in column and row lines in an imaging area of the display, wherein the display has a diagonal dimension in excess of 10 inches and has more than 150 row lines in the imaging region, and is free of line dropout defects in the image region and provides a maximum full-frame brightness of at least 50 nits.

In a further embodiment, the invention is directed towards a passive matrix OLED display comprising an array of individually addressable OLED pixels arranged in column and row lines in an imaging area of the display, wherein at least one pixel comprises at least one current-limiting component connected in series with an electroluminescent diode, and wherein the electroluminescent diode comprises a plurality of electroluminescent units connected in series between an anode and a cathode.

From another aspect, various embodiments of the present invention provide a passive matrix OLED display exhibiting, over its operating range, increasing efficiency with increasing drive current density. It is a feature of an embodiment of the present invention that it provides an OLED display using stacked OLEDs in a passive matrix design. The apparatus of various embodiments of the present invention takes advantage of the improved light efficiency of the stacked OLED design providing singlet exciton emission, while enjoying the advantage of simplicity over alternative active-matrix design solutions.

It is an advantage of various embodiments of the present invention that it provides increased display brightness over previous designs and, unlike conventional OLED devices, provides improved efficiency with increased current density.

It is an advantage of various embodiments of the present invention that it provides improved manufacturing yields for a large-scale OLED matrix.

It is an advantage of various embodiments of the present invention that it is capable of providing improved display resolution over previous designs.

These and other objects, features, and advantages of various embodiments of the present invention will become apparent to those skilled in the art upon a reading of the following detailed description when taken in conjunction with the drawings wherein there are shown and described illustrative embodiments of the invention.

### BRIEF DESCRIPTION OF THE DRAWINGS

While the specification concludes with claims particularly pointing out and distinctly claiming the subject matter of the present invention, it is believed that the invention will be better understood from the following description when taken in conjunction with the accompanying drawings, wherein:

FIG. 1 is a cutaway side view showing the basic components of an OLED pixel;

FIG. 2 is a schematic diagram showing the basic arrangement of a passive matrix OLED array;

FIGS. 3a, 3b, 3c, and 3d are schematic diagrams showing a segment of a passive matrix OLED array having a short, under various current source and row scanning conditions;

FIG. 4 is a graph showing the relationship of efficiency to current density for various arrangements of triplet-emission OLED materials;

FIGS. 5a-5d are schematic diagrams showing arrangements of pixel components in different embodiments of the present invention;

FIG. 6 is a plan view showing a large-scale OLED array fabricated according to an embodiment of the present invention;

FIG. 7 is a plan view showing an alternate embodiment of a large-scale OLED array fabricated according to the present invention;

FIG. 8 is a plan view showing another alternate embodiment of a large-scale OLED array fabricated according to the present invention;

FIG. 9 is a graph showing the relative efficiency of a stacked OLED device using singlet emission, according to an embodiment of the present invention;

FIG. 10 is a schematic showing a portion of an interleaved arrangement for an OLED display, according to an alternate embodiment;

FIG. 11 is a side view showing the structure of a stacked OLED device according to an embodiment of the present invention; and, FIGS. 12a, 12b, and 12c are an exploded perspective view, a partial side view, and a partial top view respectively, showing a tiling arrangement that can be used to increase the overall size of a display.

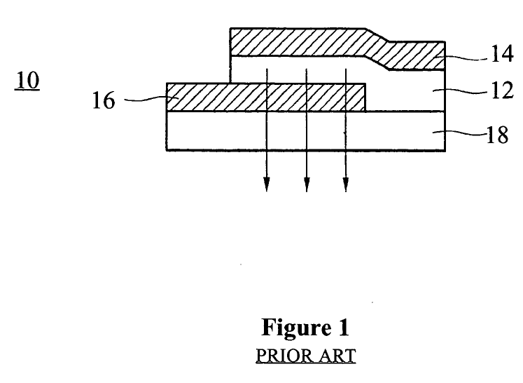

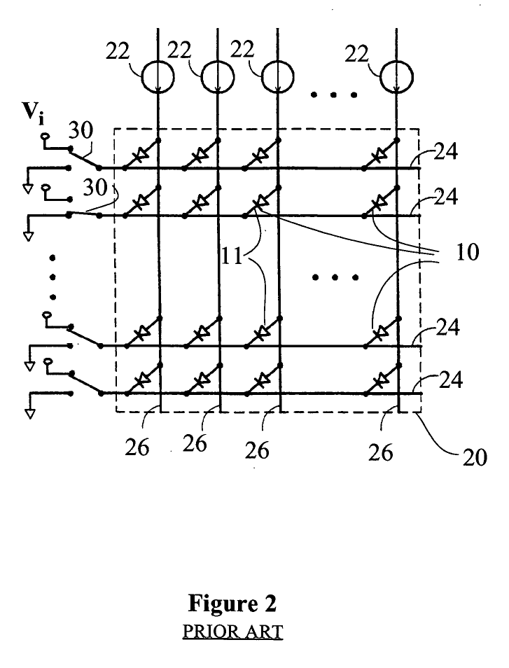

### DETAILED DESCRIPTION OF THE INVENTION

The present description is directed in particular to elements forming part of, or cooperating more directly with, apparatus in accordance with the invention. It is to be understood that elements not specifically shown or described may take various forms well known to those skilled in the art.

For commercial viability, a high-brightness display using OLED emitters must typically provide full-frame brightness of at least a threshold level of 50 nits or better. Additionally, there must be no line dropout defects in the image region of the display, such that a complete column or row of pixels is disabled by a faulted element of the display. While current designs employing passive-matrix OLED displays are typically limited to display screens having no more than about 100 row lines and being no greater than about 6 inches diagonally, the present invention enables passive-matrix OLED displays having substantially increased size and brightness. As the background material given above indicates, there are a number of hurdles that complicate the task of designing a large-scale OLED using passive matrix components, chiefly the following:
(i) Shorted pixel defects, resulting in low yields.
(ii) Drive current considerations.
(iii) Luminous efficiency characteristics of OLED emitters.
   The apparatus and method of the present invention addresses each of these considerations, and uses design techniques that provide a large-scale passive matrix OLED display having increased size and improved brightness over previous designs.
   Shorted Pixel Compensation

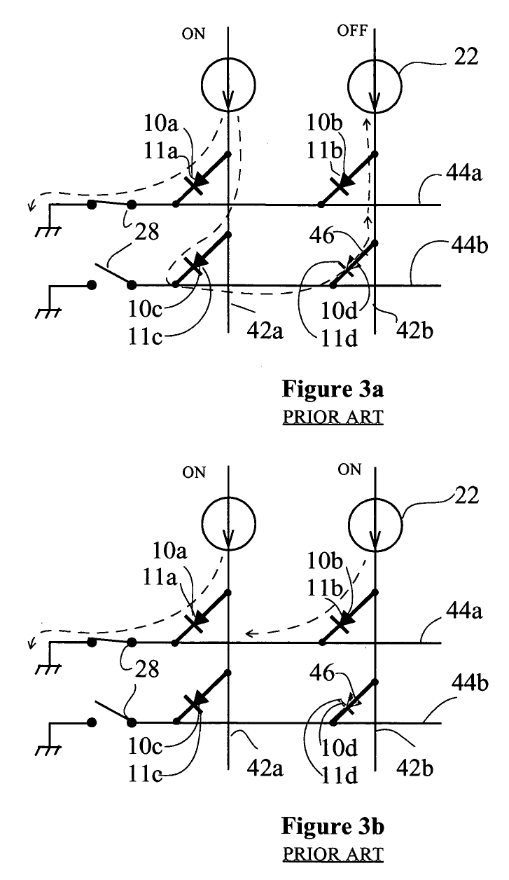

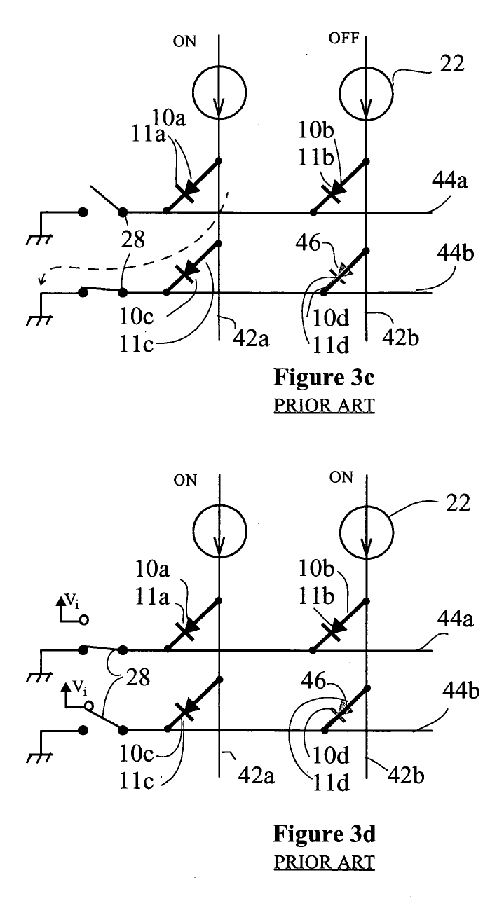

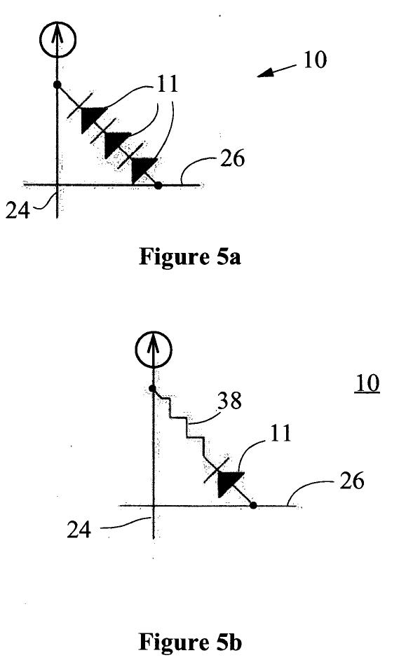

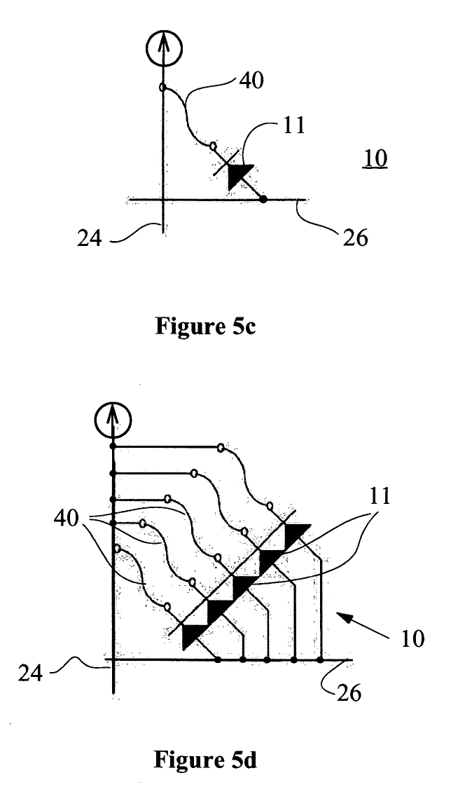

To compensate for the adverse affects of a pixel 10 shorting, as was shown with regard to FIGS. 3a-3d, the present invention employs a current-limiting component fabricated in series with the emissive diode component of pixel 10, such as described in the disclosure of commonly assigned copending U.S. patent application Ser. No. 10/773,509, incorporated herein by reference above. Various different types of current limiting elements can be used, singly or in combination, as is described for each of the embodiments outlined below. Referring to FIGS. 5a-5d, there are summarized different embodiments of the solution.

FIG. 5a shows the use of multiple diodes 11 in series as current-limiters, wherein each series diode 11 acts as a sub-pixel of the display component. With this arrangement, shorting of one electroluminescent diode 11 simply adds to the current load of the other electroluminescent diode(s) 11 connected in series within OLED pixel 10. Electroluminescent diodes 11 can be themselves the current limiting elements, in which case, each diode 11 within OLED pixel 10 provides some portion of the overall emitted light. Alternately, one or more of the series-connected diodes could be a diode that does not emit light, but simply acts as a current limiting element. Electroluminescent diodes 11 may be formed from suitably doped OLED materials arranged in series, such that the cathode of one electroluminescent diode 11 connects to the anode of the next electroluminescent diode 11. This first display embodiment admits a number of alternative arrangements. For example, the number of series electroluminescent diodes 11 can be varied based on factors such as driver characteristics. The greater the number of electroluminescent diodes 11 connected in series within OLED pixel 10, the greater is the relative insensitivity to a short condition. However, at the same time, the voltage required to drive pixel 10 increases with an increased number of series-connected electroluminescent diodes 11.

FIG. 5b shows a series resistor 38 for current limiting. The resistance value of series resistor 38 would be selected with a suitable value for limiting current if electroluminescent diode 11 is shorted. Series resistor 38 may connect from the cathode of electroluminescent diode 11; however, series connection of resistor 38 at the anode would be equivalent for providing current limiting protection. This second display embodiment also admits a number of alternative arrangements, including combination with other embodiments. For example, series resistor 38 could be used in OLED pixel 10 that contains two or more electroluminescent diodes 11.

FIG. 5c shows a series fuse 40 for current limiting. An overcurrent condition caused by shorting of electroluminescent diode 11 would blow fuse 40, effectively causing an open circuit for this OLED pixel 10. A single dark pixel would result; however, other pixels from other OLED pixel 10 would not be affected by this failure. Fuse 40 may be connected between the cathode of electroluminescent diode 11 and cathode line 24, or alternatively be connected between the anode of electroluminescent diode 11 and anode line 26. Alternative variations include series combination of fuse 40 with multiple electroluminescent diodes 11 or with other current limiting elements in series. Fuse 40 can be fabricated using any of a number of materials and techniques. Materials useful for forming fuses are generally alloys that have a relatively low melting point. In particular, binary, ternary, quaternary, and quinternary alloys selected from the elements Bi, In, Pb, Sn, and Cd are preferred. By way of example, but not of limitation, fuse 40 materials could include any of the following:
a) quinternary eutectic alloy Bi(44.7%) Pb(22.6%) In(19.1%) Sn(8.3%)Cd(5.3%) which has a melting point of 47° C.;
b) quaternary Wood's Metal (Bi(50.0%) Pb(25.0%) Sn(12.5%) Cd(12.5%)) having a melting point of 70° C.;
c) ternary eutectic Bi(52.5%) Pb(32.0%) Sn(15.5%) with a melting point of 95° C.; or
d) binary eutectic solder (Sn(63%) Pb(37%)) that melts at 183° C.
   It can be appreciated that many other, eutectic and non-eutectic alloys of these and other elements are useful for forming fuse 40.

Fuse 40 has an added advantage during fabrication of an OLED array 20. Where electroluminescent diode 11 at any pixel 10 is shorted, it would be advantageous to selectively open the circuit connection, effectively isolating and disabling pixel 10 at that location. Applying a high reverse-bias voltage to array 20 would direct a high level of current only through shorted pixels 10. By a applying a reverse-bias voltage of sufficient value, only those fuses 40 at pixels 10 having shorted electroluminescent diodes 11 would be blown. This would enable high yields. With respect to yield equation (1) given earlier, area A is greatly reduced, effectively to the dimensions of a single pixel 10 area.

FIG. 5d shows parallel diodes 11, each provided with series fuse 40. This solution helps to minimize the impact of any single diode 11 short on other diodes in the same row or column. With this arrangement, shorting of a single electroluminescent diode 11 blows its corresponding fuse 40, opening this part of the circuit, but permitting continued flow of current through other electroluminescent diodes 11 connected in parallel. Addition of a separate fusing component for providing fuse 40 may be employed, or the current-carrying capacity of OLED materials themselves, or that of nearby cathode or anode support structures, effectively may provide a fusing element with this embodiment, where an overcurrent condition is sufficient to melt or burn away conductive material that forms electroluminescent diode 11, opening the circuit at that point. A hybrid arrangement is also possible, using some combination of localized overheating of OLED material, overheating of anode or cathode segments, or use of a fuse material, as was described with respect to the third display embodiment. Alternative arrangements of this fourth embodiment also include replacing one or more fuses 40 with a corresponding series resistor 38. As another alternative, one or more parallel circuits could use an arrangement with multiple electroluminescent diodes 11 connected in series within each circuit.

Using the display embodiments of FIGS. 5a, 5b, 5c, and 5d, manufacturing yields may be increased without significant cost impact. In terms of equation (1) in the Background of the Invention, the effective area A of a fault is reduced to a pixel 10 area using these methods, rather than the area A of the complete display.

Drive Current Considerations

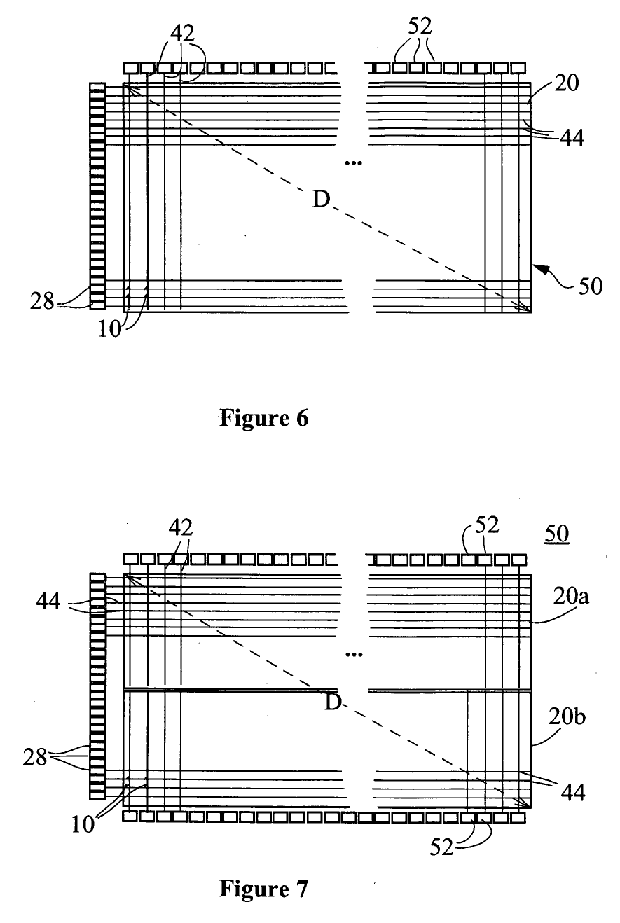

The need for higher power levels results in a requirement for driving high current through display driver circuitry. Referring to FIG. 6, there is shown an OLED display 50 using OLED array 20 with column drivers 52 that provide data acting as current sources 22 in each column 42 and row switches 28 that select individual rows 44, sinking the current for each row 44. In prior art displays, diagonal D is constrained by the number of rows 44, to no more than about 6 inches. There are inherent limitations to how many rows 44 can be used. Merely increasing the number of rows 44 is one alternative; however, this requires faster refresh rates and higher instantaneous brightness, hence higher current levels. A practical threshold of about 100 lines is obtainable using existing passive-matrix OLED designs. Using stacked OLED type configurations (described subsequently) allows for lower current levels to be employed. Thus, limitations on diagonal D based on current level limitations can be relaxed somewhat for the improved OLED emitter design disclosed in the commonly assigned Liao et al. U.S. Patent Publication No. 2003/0170491 A1 application cited above. However, some practical limitation is still imposed.

FIG. 7 shows an alternate arrangement of display 50 that allows the number of rows 44 to be doubled when compared with the FIG. 6 arrangement. Effectively, two arrays 20a and 20b are used, providing vertical “tiles”. Preferably, tiled arrays 20a and 20b are fabricated on the same substrate, and abut one another along the boundary between the arrays, giving a seamless display. Each array 20a and 20b can have up to about 100 rows using conventional OLED designs, and may even have additional rows using the improved components described herein. Since column 42 requirements are not as constraining as those for rows 44, additional columns 42 with their associated column drivers 52 can be added more easily to provide the proper aspect ratio for display 50. Using the arrangement of display 50 in FIG. 7, each array 20a or 20b may have separate row 44 timing, so that one row 44 in each array 20a or 20b is selected at a time. Thus, two rows 44 can be simultaneously selected, effectively doubling the instantaneous display brightness over previous designs. This tiling arrangement, then, can be used to provide a larger display and to provide increased brightness.

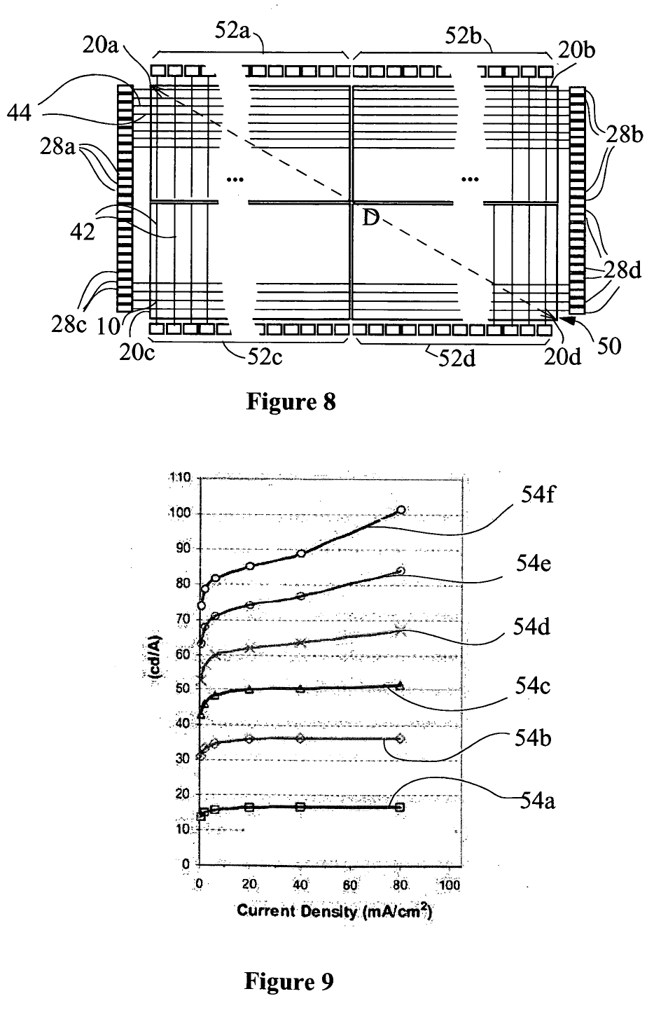

Referring to FIG. 8, another alternate tiled arrangement of display 50 is shown. Here, four arrays 20a, 20b, 20c, and 20d are placed side-by-side, each array 20a, 20b, 20c, and 20d forming a quadrant of display 50. Preferably, arrays 20a, 20b, 20c, and 20d are formed as adjacent quadrants on a single substrate and neighboring quadrants are abutting. Each respective quadrant has a corresponding set of column drivers 52a, 52b, 52c, and 52d and set of row switches 28a, 28b, 28c, and 28d. This arrangement provides the potential size and brightness benefits noted earlier with respect to the FIG. 7 configuration. In addition, by doubling the number of row switches 28, the FIG. 8 configuration offers the added advantage of reduced current handling for row 44 by each row selection switch 28a/28b/28c/28d. This reduction of maximum voltage drops (I×R, where I represents current and R resistance) along columns 42a/42b/42c/42d or rows 44a/44b/44c/44d is an important benefit of tiling schemes, such as those shown in FIGS. 7 and 8. Reducing these voltage drops can improve display uniformity, reduce electrode conductivity requirements, and reduce the required driver voltage compliance.

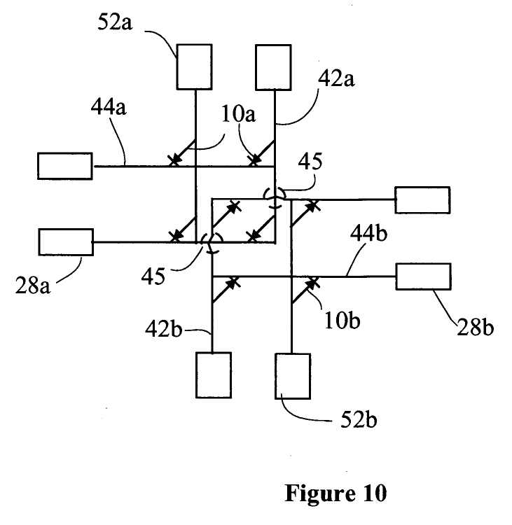

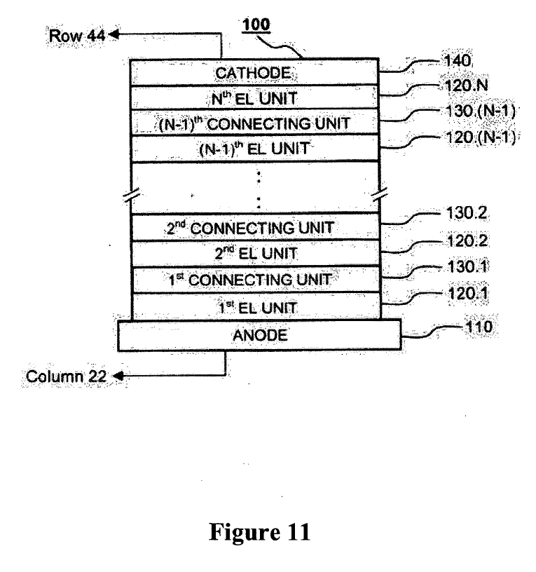

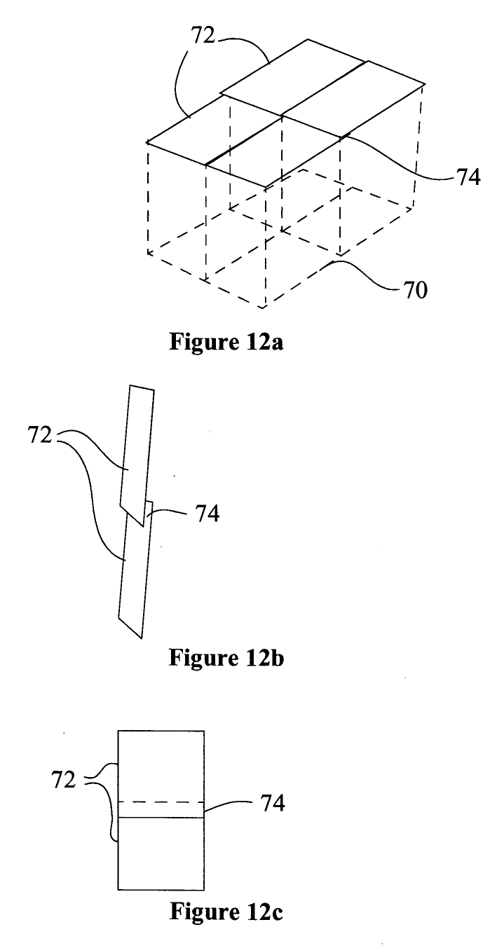

It is instructive to note that grouping using the tiled arrangement of FIGS. 7 and 8 could be performed using other arrangements, so that pixels 10 are effectively grouped in some other manner. For example, other geometrical tiling patterns could be employed, such as hexagonal arrangements. Alternately, an interleaved arrangement in which spatially adjacent rows 44 are in alternate groups or sets could be employed, as is shown in FIG. 10. Each group or set of rows 44a/44b and columns 42a/42b, along with their corresponding column drivers 52a/52b and switches 28a/28b for controlling pixels 10a/10b would then be separately controlled, allowing the simultaneous selection of multiple rows 44a/44b of display 50 for larger size and/or increased brightness. This configuration would increase the spatial frequency of the tiling arrangement, rendering any tiling imperfections less noticeable in a displayed image. An insulator 45 must be provided at electrode crossing points, as shown in dotted outline in FIG. 10.

Referring to the exploded perspective view of FIG. 12a, there is shown another “shingle” tiling arrangement that can be used to increase the overall size of a composite display 70 using passive matrix OLED devices. Here, each tile 72 could itself correspond to a tiled display 50 of FIG. 7 or 8. An overlap region 74 may be provided between adjacent tiles 72 to accommodate electrode trace patterns, as shown. FIGS. 12b and 12c show a partial perspective side view and top view of this arrangement, respectively. Overlap region 74 is shown in dotted outline in FIG. 12c. Using this type of shingled configuration, display 70 can be any arbitrary size, determined by the number of tiles 72 used.

Luminous Efficiency

High luminous efficiency can be obtained using a stacked or cascaded OLED design such as disclosed in U.S. Patent Publication No. 2003/0170491 A1 by Liao et al, incorporated by reference above. FIG. 11 shows a stacked OLED 100 for a single pixel in accordance with the present invention. Stacked OLED 100 has an anode 110 and a cathode 140, at least one of which is transparent. Disposed between anode 110 and cathode 140 are a number, N, of organic electroluminescent (EL) units 120.1, 120.2, 120.(N−1), 120.N in tandem, where N is an integer greater than 1. Organic EL units 120.1 to 120.N are stacked in series between anode 110 and cathode 140; in the representation of FIG. 11, EL unit 120.1 connects directly to anode 110 and EL unit 120.N connects directly to cathode 140, with intermediate EL units 120.2 to 120.(N−1) stacked between. Disposed between any two adjacent EL units 120.1 to 120.N is a corresponding connecting unit 130.1 to 130.(N−1) . For example, connecting unit 130.1 is disposed between organic EL units 120.1 and 120.2. There are, then, a total of (N−1) connecting units 130 associated with N organic EL units 120.1 to 120.(N−1) . Using this internal arrangement, stacked OLED 100 provides a single pixel 10 at a specific column 42 and row 44 intersection within OLED array 20.

To function efficiently, the connecting unit for the stacked OLED should provide electron injection into the electron-transporting layer and hole injection into the hole-transporting layer of the two adjacent organic EL units. A variety of materials may be used to form the connecting units. In preferred embodiments, connecting unit materials are selected to provide high optical transparency and excellent charge injection, thereby providing the stacked OLED high electroluminescence efficiency and operation at an overall low driving voltage.

The connecting unit may comprise, e.g., doped organic connectors provided between adjacent organic EL units such as disclosed in U.S. Patent Publication No. 2003/0170491 A1. Each doped organic connector may include at least one n-type doped organic layer,. or at least one p-type doped organic layer, or a combination of layers, thereof. Preferably, the doped organic connector includes both an n-type doped organic layer and a p-type doped organic layer disposed adjacent to one another to form a p-n heterojunction. It is also preferred that the n-type doped organic layer is disposed towards the anode side, and the p-type doped organic layer is disposed towards the cathode side. The choice of using n-type doped organic layer, or a p-type doped organic layer, or both (the p-n junction) is in part dependent on the organic materials that include the organic EL units. Each connector can be optimized to yield the best performance with a particular set of organic EL units. This includes choice of materials, layer thickness, modes of deposition, and so forth.

An n-type doped organic layer means that the organic layer has semiconducting properties after doping, and the electrical current through this layer is substantially carried by the electrons. A p-type doped organic layer means that the organic layer has semiconducting properties after doping, and the electrical current through this layer is substantially carried by the holes. A p-n heterojunction means an interfacial region (or junction) formed when a p-type layer and an n-type layer contact each other.

N-type doped organic layers may include a host organic material and at least one n-type dopant. The host material in the n-typed doped organic layer can include a small molecule material or a polymeric material, or combinations thereof, and it is preferred that it can support electron transport. The p-type doped organic layers may include a host organic material and at least one p-type dopant. The host material can include a small molecule material or a polymeric material, or combinations thereof, and it is preferred that it can support hole transport. In some instances, the same host material can be used for both n-typed and p-type doped organic layers, provided that it exhibits both hole and electron transport properties set forth above. The n-type doped concentration or the p-type doped concentration is preferably in the range of 0.01-10 vol. %. The total thickness of each doped organic connector is typically less than 100 nm, and preferably in the range of about 1 to 100 nm.

The organic electron-transporting materials used in conventional OLED devices represent a useful class of host-materials that may be employed for the n-type doped organic layer. Preferred materials are metal chelated oxinoid compounds, including chelates of oxine itself (also commonly referred to as 8-quinolinol or 8-hydroxyquinoline), such as tris(8-hydroxyquinoline) aluminum. Other materials include various butadiene derivatives as disclosed by Tang (U.S. Pat. No. 4,356,429), various heterocyclic optical brighteners as disclosed by Van Slyke and Tang and others (U.S. Pat. No. 4,539,507), triazines, hydroxyquinoline derivatives, and benzazole derivatives. Silole derivatives, such as 2,5-bis(2′,2″-bipridin-6-yl)-1,1-dimethyl-3,4-diphenyl silacyclopentadiene as reported by Murata and others [Applied Physics Letters, 80, 189 (2002)], are also useful host materials.

Materials useful as n-type dopants in the n-type doped organic layer of a doped organic connector include metals or metal compounds having a work function less than 4.0 eV. Particularly useful dopants include alkali metals, alkali metal compounds, alkaline earth metals, and alkaline metal compounds. The term “metal compounds” includes organometallic complexes, metal-organic salts, and inorganic salts, oxides and halides. Among the class of metal-containing n-type dopants, Li, Na, K, Rb, Cs, Mg, Ca, Sr, Ba, La, Ce, Sm, Eu, Tb, Dy, or Yb, and their compounds, are particularly useful. Materials useful as n-type dopants in the n-type doped organic layer of a doped organic connector also include organic reducing agents with strong electron-donating properties. By “strong electron-donating properties” we mean that the organic dopant should be able to donate at least some electronic charge to the host to form a charge-transfer complex with the host. Non-limiting examples of organic molecules include bis(ethylenedithio)-tetrathiafulvalene (BEDT-TTF), tetrathiafulvalene (TTF), and their derivatives. In the case of polymeric hosts, the dopant can be any of the above or also a material molecularly dispersed or copolymerized with the host as a minor component.

The hole-transporting. materials used in conventional OLED devices represent a useful class of host materials for p-type doped organic layers. Preferred materials include aromatic tertiary amines having at least one trivalent nitrogen atom that is bonded only to carbon atoms, at least one of which is a member of an aromatic ring. In one form the aromatic tertiary amine can be an arylamine, such as a monoarylamine, diarylamine, triarylamine, or a polymeric arylamine. Other suitable triarylamines substituted with one or more vinyl radicals and/or comprising at least one active hydrogen-containing group are disclosed by Brantley and others (U.S. Pat. No. 3,567,450 and U.S. Pat. No. 3,658,520). A more preferred class of aromatic tertiary amines are those which include at least two aromatic tertiary amine moieties as described by Van Slyke and Tang and others (U.S. Pat. No. 4,720,432 and U.S. Pat. No. 5,061,569). Non-limiting examples include as N,N′-di(naphthalene-1-yl)-N,N′-diphenyl-benzidine (NPB) and N,N′-diphenyl-N,N′-bis(3-methylphenyl)-1,1-biphenyl-4,4′-diamine (TPD), and N,N,N′,N′-tetranaphthyl-benzidine (TNB).

Materials useful as p-type dopants in p-type doped organic layers of doped organic connectors-include oxidizing agents with strong electron-withdrawing properties. By “strong electron-withdrawing properties” we mean that the organic dopant should be able to accept some electronic charge from the host to form a charge-transfer complex with the host. Some non-limiting examples include organic compounds such as 2,3,5,6-tetrafluoro-7,7,8,8-tetracyanoquinodimethane (F₄-TCNQ) and other derivatives of TCNQ, and inorganic oxidizing agents such as iodine, FeCl₃, SbCl₅, and some other metal chlorides. In the case of polymeric hosts, the dopant can be any of the above or also a material molecularly dispersed or copolymerized with the host as a minor component.

Examples of materials that can be used as host for either n-type or p-type doped organic layers include, but are not limited to: various anthracene derivatives including those described in U.S. Pat. No. 5,972,247; certain carbazole derivatives, such as 4,4-bis(9-dicarbazolyl)-biphenyl (CBP); and distyrylarylene derivatives such as 4,4′-bis(2,2′-diphenyl vinyl)-1,1′-biphenyl and as described in U.S. Pat. No. 5,121,029. The materials used for fabricating doped organic connectors are preferably substantially transparent to emitted light.

In a preferred embodiment, the connecting unit comprises, in sequence, an n-type doped organic layer and a p-type doped organic layer. Thus, in this structure, the ETL of the EL unit is adjacent to the n-type doped layer of the connecting unit and the HTL of the EL unit is adjacent to the p-type doped connecting unit. In this stacked device structure only a single external power source is needed to connect to the anode and the cathode with the positive potential applied to the anode and the negative potential to the cathode. No other electrical connections are needed to connect the individual organic EL units to external electrical power sources.

In a further specific stacked OLED device embodiment, the physical spacing between adjacent electroluminescent zones may be more than 90 nm and the connecting unit disposed between each adjacent organic electroluminescent unit may comprise an n-type doped organic layer and a p-type doped organic layer forming a transparent p-n junction structure wherein the resistivity of each of the doped layers is higher than 10 Ω-cm, as described in commonly assigned U.S. patent application Ser. No. 10/437,195 filed May 13, 2003 entitled “Cascaded Organic Electroluminescent Device Having Connecting Units with n-Type and p-Type Organic Layers”, the disclosure of which is herein incorporated by reference.

For a stacked OLED to function efficiently, it is necessary that the optical transparency of the layers constituting the organic EL units and the connecting units be as high as possible to allow for radiation generated in the organic EL units to exit the device. Furthermore, for the radiation to exit through the anode, the anode should be transparent and the cathode can be opaque, reflecting, or transparent. For the radiation to exit through the cathode, the cathode should be transparent and the anode can be opaque, reflecting or transparent. The layers constituting the organic EL units are generally optically transparent to the radiation generated by the EL units, and therefore their transparency is generally not a concern for the construction for the stacked OLEDs.

The operational stability of stacked OLED is dependent to a large extent on the stability of the connecting units. In particular, the driving voltage will be highly dependent on whether or not the connecting unit can provide the necessary electron and hole injection. It is generally known that the close proximity of two dissimilar materials may result in diffusion of matters from one into another, or in interdiffusion of matters across the boundary between the two. In the case of stacked OLEDs employing an n-type doped organic layer and a p-type doped organic layer, if such diffusion were to occur in the connecting unit between the n-type doped organic layer and the p-type doped organic layer, the injection properties of this organic connecting unit may degrade correspondingly due to the fact that the individual n-type doped layer or p-type doped layer may no longer be sufficiently electrically conductive. Diffusion or interdiffusion is dependent on temperature as well as other factors such as electrical field induced migration. The latter is plausible in stacked OLED devices since the operation of OLED generally requires an electric field as high as 10⁶ volt per centimeter. To prevent such an operationally induced diffusion in the connecting units of a stacked OLED, an interfacial layer which provides a barrier for interfusion may be introduced in between the n-type doped layer and the p-type doped layer, as described in U.S. Pat. No. 6,717,358, the disclosure of which is incorporated herein by reference.

Interfacial layers useful in the connecting unit may comprise at least one inorganic semiconducting material or combinations of more than one of the semiconducting materials. Suitable semiconducting materials should have an electron energy band gap less than 4.0 eV. The electron energy band gap is defined as the energy difference between the highest occupied molecular orbital and the lowest unoccupied molecular orbital of the molecule. A useful class of materials can be chosen from the compounds of elements listed in groups IVA, VA, VIA, VIIA, VIIIA, IB, IIB, IIIB, IVB, and VB in the Periodic Table of the Elements (e.g. the Periodic Table of the Elements published by VWR Scientific Products). These compounds include the carbides, silicides, nitrides, phosphides, arsenides, oxides, sulfides, selenides, and tellurides, and mixture thereof. These semiconducting compounds can be in either stoichoimetic or non-stoichiometic states, that is they may contain excess or deficit metal component. Particularly useful materials for the interfacial layer are the semiconducting oxides of titanium, zirconium, hafnium, vanadium, niobium, tantalum, chromium, molybdenum, tungsten, manganese, rhenium, iron, ruthenium, osmium, cobalt, rhodium, iridium, nickel, palladium, platinum, copper, zinc, cadmium, gallium, thallium, silicon, germanium, lead, and antimony, or combinations thereof. Particularly useful materials for the interfacial layer also include zinc selenide, gallium nitride, silicon carbide, or combinations thereof.

The interfacial layer useful in a connecting unit also can comprise at least one or more metallic materials, where at least one of these metallic materials has a work-function higher than 4.0 eV as listed by Sze, in Physics of Semiconducting Devices, 2^{nd} Edition, Wiley, N.Y., 1981, p. 251. The thickness of an interfacial layer suitable for the construction of a connecting unit is preferably in the range of 0.05 nm to 10 nm, more preferably between 0.1 nm to 5 nm for inorganic semiconducting materials and between 0.05 nm to 1 nm for metallic materials.

In a further embodiment, the connecting unit disposed between each adjacent organic electroluminescent unit in the stacked device may include at least a high work function metal layer having a work function of no less than 4.0 eV and a metal compound layer, wherein the intermediate connector has a sheet resistance of higher than 100 kΩ per square, such as described in copending, commonly assigned U.S. Ser. No. 10/857,516, filed May 28, 2004, the disclosure of which is incorporated herein by reference. The use of such high work function metal layer in a connecting unit of a stacked OLED device improves the operational stability of the OLED.

As discussed above, for a stacked OLED to function efficiently, it is necessary that the intermediate connector should provide good carrier injection into the adjacent organic EL units. Due to their lower resistivity than that of organic materials, metals, metal compounds, or other inorganic compounds can be good for carrier injection. However, low resistivity can cause low sheet resistance resulting in pixel crosstalk. If the lateral current passing through the adjacent pixels to cause pixel crosstalk is limited to less than 10% of the current used to drive a pixel, the lateral resistance of the intermediate connector (R_{ic}) should be at least 8 times the resistance of the stacked OLED. Usually, the static resistance between two electrodes of a conventional OLED is about several kΩs, and a stacked OLED should have a resistance of about 10 kΩ or several 10 kΩs between the two electrodes. Therefore R_{ic} should be greater than 100 kΩ. Considering the space between each pixel is smaller than one square, the sheet resistance of the intermediate connector should be then greater than 100 kΩ per square (lateral resistance equals to sheet resistance times the number of square). Because the sheet resistance is determined by both the resistivity and the thickness of the films (sheet resistance equals to film resistivity divided by film thickness), when the layers constituting an intermediate connector are selected from metals, metal compounds, or other inorganic compounds having low resistivity, a sheet resistance of the intermediate connector greater than 100 kΩ per square can still be achievable if the layers are thin enough.

Another requirement for the stacked OLED to function efficiently is that the optical transparency of the layers constituting the organic EL units and the intermediate connectors be as high as possible to permit for radiation produced in the organic EL units to exit the device. According to a simple calculation, if the optical transmission of each intermediate connector is 70% of the emitting light, a stacked OLED will not have much benefit because no matter how many EL units there are in the device, the electroluminance efficiency can never be doubled when comparing to a conventional device. The layers constituting the organic EL units are generally optically transparent to the radiation produced by the EL units, and therefore their transparency is generally not a concern for the construction of the stacked OLEDs. As is known, metals, metal compounds, or other inorganic compounds can have low transparency. However, when the layers constituting an intermediate connector are selected from the metals, metal compounds, or other inorganic compounds, an optical transmission higher than 70% can still be achievable if the layers are thin enough. Preferably, the intermediate connector has at least 75% optical transmission in the visible region of the spectrum.

In accordance with one specific embodiment, the intermediate connectors may comprise, in sequence, a low work function metal layer, a high work function metal layer, and a metal compound layer. Herein, a low work function metal is defined as a metal having a work function less than 4.0 eV. Likewise, a high work function metal is defined as a metal having a work function no less than 4.0 eV. The low work function metal layer is preferably disposed adjacent to the ETL of an organic EL unit towards the anode side, and the metal compound layer is preferably disposed adjacent to the HTL of another organic EL unit towards the cathode side. The low work function metal layer may be selected to provide efficient electron injection into the adjacent electron-transporting layer. The metal compound layer may be selected to provide efficient hole injection into the adjacent hole-transporting layer. Preferably, the metal compound layer comprises, but is not limited to, a p-type semiconductor. The high work function metal layer is selected to improve the operational stability of the OLED by preventing a possible interaction or interdiffusion between the low work function layer and the metal compound layer.

In accordance with another specific embodiment, the intermediate connectors may comprise, in sequence, an n-type semiconductor layer, a high work function metal layer, and a metal compound layer. The n-type semiconductor layer is preferably disposed adjacent to the ETL of an organic EL unit towards the anode side, and the metal compound layer is preferably disposed adjacent to the HTL of another organic EL unit towards the cathode side. Herein, an n-type semiconductor layer means that the layer is electrically conductive having electrons as the major charge carriers. Likewise, a p-type semiconductor layer means that the layer is electrically conductive having holes as the major charge carriers. Similar to a low work function metal layer, the n-type semiconductor layer may be selected to provide efficient electron injection into the adjacent electron-transporting layer. The metal compound layer again may be selected to provide efficient hole injection into the adjacent hole-transporting layer, and the high work function metal layer is selected to improve the operational stability of the OLED by preventing a possible interaction or interdiffusion between the n-type semiconductor layer and the metal compound layer.

In the case such that the ETL in the EL unit is an n-type doped organic layer, the layer structure of the intermediate connector can be simplified by comprising, in sequence, a high work function metal layer disposed adjacent to the n-type doped ETL of an organic EL unit towards the anode side, and a metal compound layer disposed adjacent to the HTL of another organic EL unit towards the cathode side. The metal compound layer may be selected to provide efficient hole injection into the adjacent hole-transporting layer, and the high work function metal layer is selected to improve the operational stability of the OLED by preventing a possible interaction or interdiffusion between the n-type doped ETL and the metal compound layer. Herein, an n-type doped organic layer means that the layer is electrically conductive, and the charge carriers are primarily electrons. The conductivity is provided by the formation of a charge-transfer complex as a result of electron transfer from the dopant to the host material. Depending on the concentration and the effectiveness of the dopant in donating an electron to the host material, the layer electrical conductivity can change by several orders of magnitude. With an n-type doped organic layer as an ETL in the EL unit, electrons can be efficiently injected from the adjacent intermediate connector into the ETL.

In order for the intermediate connectors to have good optical transmission (at least 75% optical transmission in the visible region of the spectrum), good carrier injection capability, and good operational stability, the thickness of the layers in the intermediate connectors has to be carefully considered. The thickness of the low work function metal layer, when employed, in the intermediate connectors is preferably in the range of from 0.1 nm to 5.0 nm, more preferably in the range of from 0.2 nm to 2.0 nm. The thickness of the high work function metal layer, when employed, in the intermediate connectors is preferably in the range of from 0.1 nm to 5.0 nm, more preferably in the range of from 0.2 nm to 2.0 nm. The thickness of the metal compound layer, when employed, in the intermediate connectors is preferably in the range of from 0.5 nm to 20 nm, more preferably in the range of from 1.0 nm to 5.0 nm. The thickness of the n-type semiconductor layer, when employed, in the intermediate connectors is preferably in the range of from 0.5 nm to 20 nm, more preferably in the range of from 1.0 nm to 5.0 nm.

The materials used for the fabrication of intermediate connectors are basically selected from nontoxic materials. Low work function metal layers may include, e.g., Li, Na, K, Rb, Cs, Mg, Ca, Sr, Ba, La, Ce, Nd, Sm, Eu, Tb, Dy, or Yb. Preferably, the low work function metal layer includes Li, Na, Cs, Ca, Ba, or Yb. High work function metal layers may include, e.g., Ti, Zr, Ti, Nb, Ta, Cr, Mo, W, Re, Fe, Ru, Os, Co, Rh, Ir, Ni, Pd, Pt, Cu, Ag, Au, Zn, Al, In, or Sn. Preferably, the high work function metal layer includes Ag, Al, Cu, Au, Zn, In, or Sn. More preferably, the high work function metal layer includes Ag or Al.

The metal compound layer, when employed, can be selected from the stoichiometric oxides or nonstoichiometric oxides of titanium, zirconium, hafnium, niobium, tantalum, molybdenum, tungsten, manganese, iron, ruthenium, rhodium, iridium, nickel, palladium, platinum, copper, zinc, silicon, or germanium, or combinations thereof. The metal compound layer can be selected from the stoichiometric sulfides or nonstoichiometric sulfides of titanium, zirconium, hafnium, niobium, tantalum, molybdenum, tungsten, manganese, iron, ruthenium, rhodium, iridium, nickel, palladium, platinum, copper, silicon, or germanium, or combinations thereof. The metal compound layer can be selected from the stoichiometric selenides or nonstoichiometric selenides of titanium, zirconium, hafnium, niobium, tantalum, molybdenum, tungsten, manganese, iron, ruthenium, rhodium, iridium, nickel, palladium, platinum, copper, silicon, or germanium, or combinations thereof. The metal compound layer can be selected from the stoichiometric tellurides or nonstoichiometric tellurides of titanium, zirconium, hafnium, niobium, tantalum, molybdenum, tungsten, manganese, iron, ruthenium, rhodium, iridium, nickel, palladium, platinum, copper, silicon, or germanium, or combinations thereof. The metal compound layer can be selected from the stoichiometric nitrides or nonstoichiometric nitrides of titanium, zirconium, hafnium, niobium, tantalum, molybdenum, tungsten, manganese, iron, ruthenium, rhodium, iridium, nickel, palladium, platinum, copper, zinc, gallium, silicon, or germanium, or combinations thereof. The metal compound layer can also be selected from the stoichiometric carbides or nonstoichiometric carbides of titanium, zirconium, hafnium, niobium, tantalum, molybdenum, tungsten, manganese, iron, ruthenium, rhodium, iridium, nickel, palladium, platinum, copper, zinc, aluminum, silicon, or germanium, or combinations thereof. The metal compound layer can be selected from MoO₃, NiMoO₄, CuMoO₄, WO₃, ZnTe, Al₄C₃, AlF₃, B₂S₃, CuS, GaP, InP, or SnTe. Preferably, the metal compound layer is selected from MoO₃, NiMoO₄, CuMoO₄, or WO₃.

The n-type semiconductor layer, when employed, may include, e.g., ZnSe, ZnS, ZnSSe, SnSe, SnS, SnSSe, LaCuO₃, or La₄Ru₆O₁₉. Preferably, the n-type semiconductor layer includes ZnSe or ZnS.

Other intermediate connector materials may also be employed in the OLED stacked devices. For example, Tanaka et al., U.S. Pat. No. 6,107,734, demonstrated a 3-EL-unit OLED using In—Zn—O (IZO) films or Mg:Ag/IZO films as intermediate connectors and achieved a luminous efficiency of 10.1 cd/A from pure tris(8-hydroxyquinoline)aluminum emitting layers. Kido et al. U.S. Patent Publication 2003/0189401 A1 discloses the use of light-emissive units partitioned from each other by at least one charge generation layer, the charge generation layer constituting an electrically insulating layer having a resistivity of not less than 1.0×10 2 Ωcm. Kido et al., “High Efficiency Organic EL Devices having Charge Generation Layers”, SID 03 Digest, 964 (2003), fabricated 3-EL-unit OLEDs using In—Sn—O (ITO) films or V₂O₅ films as intermediate connectors and achieved a luminous efficiency of up to 48 cd/A from fluorescent dye doped emitting layers. The disclosures of the above references with respect to intermediate connector materials are herein incorporated by reference.

The intermediate connectors layers, including interfacial layers, can be produced, e.g., by thermal evaporation, electron beam evaporation, or ion sputtering technique. Preferably, the intermediate connectors are fabricated from materials which allow for a thermal evaporation method for the deposition of all the materials in the fabrication of the stacked OLED, including the intermediate connectors.

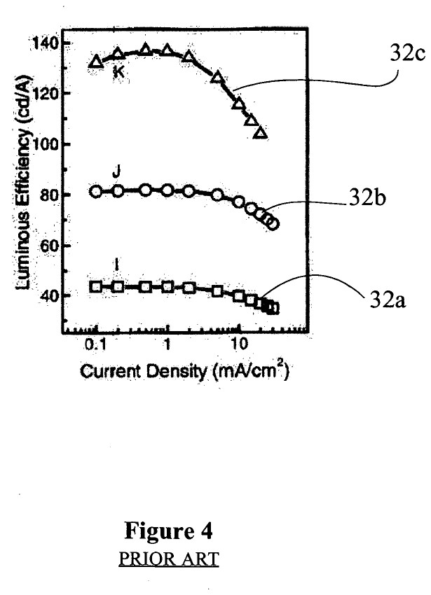

Unlike the conventional approach for brightness enhancement, it is preferred to employ singlet, rather than triplet, exciton emission in stacked OLED devices employed in the present invention. Unlike the characteristic curves of FIG. 4, in which efficiency for triplet emission shows a dramatic decline at current densities above 1 mA/cm², stacked OLEDs 100 of FIG. 11 provide increased efficiency relative to current density, with each added luminescent diode component (that is, with each added organic EL unit 120.1 to 120.N) in the stack when singlet exciton emission materials are employed. For example, several stacked OLEDs of the type illustrated in FIG. 11 having singlet exciton emission were fabricated. Each EL unit in the stacked OLEDs comprised a 20 nm layer of 4,4′-bis[N-(1-naphthyl)-N-phenylamino]biphenyl (NPB) and a 20 nm layer of tris(8-hydroxyquinoline)aluminum (Alq) doped with 1.0 vol. % of C545T. Each connecting unit (or intermediate connector) comprised a 40 nm layer of Alq doped with 1.2 vol. % Lithium and an approx. 70 nm layer of 4,4′,4″-tris(N-3-metylphenyl-N-phenyl-amino)-triphenylamine (m-MTDATA) doped with about 3 vol. % 2,3,5,6-tetrafluoro-7,7,8,8-tetracyanoquinodimethane (F4-TCNQ). In addition, there was an extra organic hole-injecting layer of 80 nm m-TDATA doped with about 3 vol. % F4-TCNQ in between the anode and the first EL unit, and there was an extra organic electron-injecting layer of 40 nm Alq doped with 1.2 vol. % lithium in between the last EL unit and the cathode for the optimization of the optical path. Referring now to the graph of FIG. 9, curves 54a, 54b, 54c, 54d, 54e, and 54f compare the efficiency characteristics of such fabricated devices having one, two, three, four, five, and six tandem EL units 120.1-120.6 in the stacked OLED of this type, over its operating range.

As FIG. 9 shows, when there are more than three EL units 120.1-120.3 in stacked OLED 100, the luminous efficiency (in Cd/A) actually continues to increase with an increase in drive current density above 20 mA/cm². Thus, using stacked OLED devices of the type taught in U.S. Patent Publication No. 2003/0170491 A1 employing singlet, exciton emission materials, the more EL units 120.1-120.N used (that is, the higher the value of N), the greater the increase in luminous efficiency over its operating range. This improvement enables the fabrication of a high efficiency OLED display, where a high-efficiency OLED display can be defined as one that provides efficiency in excess of about 30 cd/A at a current density of about 20 mA/cm². This can be contrasted with conventional OLED display devices that provide, at best, a few Cd/A at comparable current densities.

Thus it can be seen that limitations of passive matrix OLED display design, thought to be inherent to passive matrix technology itself, can be overcome using a combination of techniques, thereby providing the potential for increased display size and improved brightness, achieving or exceeding a full-frame brightness threshold of about 50 nits and free of line dropout defects (in which a complete row 44 or complete column 42 of pixels 10 is disabled due to a fault at one or more pixels 10 in the row 44 or column 42). Moreover, devices exhibiting increased efficiency with increased drive current beyond a nominal current density of about 1 mA/cm² can be fabricated using stacked OLED techniques, surmounting conventional efficiency limitations. For example, the high efficiency of the stacked OLED design as shown in FIG. 11 can be combined with the use of current-limiting in-series components of FIGS. 5a, 5b, 5c, and 5d to fabricate passive matrix OLED displays of relatively large size (e.g., greater than 10 inches diagonal with more than 150 row lines) in high yield, while still meeting practical full-frame brightness requirements of above 50 nits. Multiple OLED displays fabricated in this way can then be tiled together in any of the arrangements of FIGS. 7, 8, and 12 to further increase the available display area. Unlike conventional approaches directed to active matrix components, the apparatus and method of the present invention allow better use of passive matrix design, making available advantages such as lower cost and more straightforward fabrication techniques.

Thus, what is provided is an apparatus and method for forming a passive matrix OLED display having significantly increased surface area and improved brightness over previous passive matrix OLED designs. The invention has been described in detail with particular reference to certain preferred embodiments thereof, but it will be understood that variations and modifications can be effected within the scope of the invention as described above, and as noted in the appended claims, by a person of ordinary skill in the art without departing from the scope of the invention. For example, row 44 and column 42 designations shown in FIGS. 6, 7, and 8 could be exchanged or inverted without changing the nature of the invention.

1. A passive matrix OLED display comprising an array of individually addressable OLED pixels arranged in column and row lines in an imaging area of the display, wherein the display has a diagonal dimension in excess of 10 inches and has more than 150 row lines in the imaging region, and is free of line dropout defects and provides a maximum full-frame brightness of at least 50 nits.

2. A passive matrix OLED display according to claim 1 wherein at least one OLED pixel exhibits, over its operating range, increasing efficiency with increasing drive current density.

3. A passive matrix OLED display according to claim 1 wherein at least one OLED pixel comprises at least one current-limiting component connected in series with an electroluminescent diode.

4. A passive matrix OLED display according to claim 3 wherein the current-limiting component is taken from the set consisting of a resistor, a fuse, a second electroluminescent diode and a non-luminescent diode.

5. A passive matrix OLED display according to claim 1 having a diagonal dimension in excess of 15 inches.

6. A passive matrix OLED display according to claim 1 comprising at least one OLED pixel comprising a plurality of electroluminescent units connected in series between an anode and a cathode.

7. A passive matrix OLED display according to claim 6 wherein the at least one OLED pixel further comprises at least one current-limiting component connected in series with the plurality of electroluminescent units.

8. A passive matrix OLED display according to claim 1 having a diagonal dimension in excess of 20 inches.

9. A passive matrix OLED display according to claim 1 comprising:
(a) a first array of passive matrix OLED pixels in rows and columns, the first array comprising a first set of column drivers and a first set of row selection switches; and,
(b) a second array of passive matrix OLED pixels in rows and columns, the second array comprising a second set of column drivers and a second set of row selection switches;
such that the OLED display is capable of simultaneous light emission from both a row of the first array and a row of the second array.

10. A passive matrix OLED display according to claim 9, wherein the second array abuts the first array.

11. A passive matrix OLED display according to claim 9 wherein the second array overlaps the first array along an edge.

12. A passive matrix OLED display according to claim 9 wherein the first and second arrays share a common substrate.

13. A passive matrix OLED display according to claim 9 wherein the diagonal dimension of each array exceeds 10 inches and each array has more than 150 row lines.

14. A passive matrix OLED display according to claim 1 comprising:
(a) a first array of passive matrix OLED pixels in rows and columns, the first array comprising a first set of column drivers and a first set of row selection switches;
(b) a second array of passive matrix OLED pixels in rows and columns, the second array comprising a second set of column drivers and a second set of row selection switches;
(c) a third array of passive matrix OLED pixels in rows and columns, the third array comprising a third set of column drivers and a third set of row selection switches;
(d) a fourth array of passive matrix OLED pixels in rows and columns, the fourth array comprising a fourth set of column drivers and a fourth set of row selection switches;
such that the OLED display is capable of simultaneous light emission from a row in each of the first, second, third, and fourth arrays;
wherein each of the first, second, third, and fourth arrays forms a quadrant of a tiled array.

15. A passive matrix OLED display according to claim 14 wherein the neighboring quadrants are abutting.

16. A passive matrix OLED display according to claim 14 wherein the second array overlaps the first array along an edge, and the third array overlaps the fourth array along an edge.

17. A passive matrix OLED display according to claim 14 wherein the first, second, third, and fourth arrays share a common substrate.

18. A passive matrix OLED display according to claim 14 wherein the diagonal dimension of each quadrant exceeds 10 inches and each quadrant has more than 150 row lines.

19. A passive matrix OLED display comprising an array of individually addressable OLED pixels arranged in column and row lines in an imaging area of the display, wherein at least one pixel comprises at least one current-limiting component connected in series with an electroluminescent diode, and wherein the electroluminescent diode comprises a plurality of electroluminescent units connected in series between an anode and a cathode.

20. A passive matrix OLED display according to claim 19, wherein electroluminescent units of the electroluminescent diode comprise singlet exciton emission, and the pixel exhibits, over its operating range, increasing efficiency with increasing drive current density.

21. A passive matrix OLED display according to claim 19 wherein the current-limiting component is taken from the set consisting of a resistor, a fuse, a second electroluminescent diode, and a non-luminescent diode.

22. A passive matrix OLED display according to claim 19 wherein the diagonal surface dimension of the imaging area is in excess of 10 inches and wherein the number of display lines exceeds 150.

23. A passive matrix OLED display according to claim 19 wherein the diagonal surface dimension of the imaging area is in excess of 15 inches.

24. A passive matrix OLED display according to claim 19 wherein the diagonal surface dimension of the imaging area is in excess of 20 inches.

25. A passive matrix OLED display according to claim 19 wherein the display is free of line dropout defects.

26. A passive matrix OLED display according to claim 19 comprising:
(a) a first array of passive matrix OLED pixels in rows and columns, the first array comprising a first set of column drivers and a first set of row selection switches; and,
(b) a second array of passive matrix OLED pixels in rows and columns, the second array comprising a second set of column drivers and a second set of row selection switches;
such that the OLED display is capable of simultaneous light emission from both a row of the first array and a row of the second array.

27. A passive matrix OLED display according to claim 26 wherein the second array abuts the first array.

28. A passive matrix OLED display according to claim 26 wherein the second array overlaps the first array along an edge.

29. A passive matrix OLED display according to claim 26 wherein the first and second arrays share a common substrate.

30. A passive matrix OLED display according to claim 26 wherein the diagonal dimension of each array exceeds 10 inches and each array has more than 150 row lines.

31. A passive matrix OLED display comprising an array of individually addressable OLED pixels arranged in column and row lines in an imaging area of the display, wherein the display has a diagonal dimension in excess of 10 inches and has more than 150 row lines in the imaging region, and exhibits, over its operating range, increasing efficiency with increasing drive current density.

32. A method for forming a passive matrix OLED display comprising an array of a plurality of individually addressable OLED pixels arranged in column and row lines on a substrate in an imaging area of the display, the method comprising:
(a) forming each pixel in the plurality of pixels by series-connecting, between an anode and a cathode, a plurality of electroluminescent units; and
(b) series-connecting at least one current-limiting component to the plurality of electroluminescent units for each pixel.

33. A method according to claim 32 wherein the step of series-connecting a current-limiting component comprises the step of series connecting a resistor.

34. A method according to claim 32 wherein the step of series-connecting a current-limiting component comprises the step of series connecting a fuse.

35. A method according to claim 32 wherein the step of series-connecting a current-limiting component comprises the step of series connecting an additional electroluminescent component.

36. A method according to claim 32 wherein the step of series-connecting a current-limiting component comprises the step of series connecting a non-luminescent diode.

37. A method according to claim 32, wherein multiple arrays of OLED pixels arranged in column and row lines are formed in the imaging area of the display, where each pixel in each array is formed by series-connecting, between an anode and a cathode, a plurality of electroluminescent units and series-connecting at least one current-limiting component to the plurality of electroluminescent units for each pixel, and
wherein the multiple arrays of OLED pixels are formed on the same substrate.
